(19) United States
(12) Patent Application Publication
(10) Pub. No.: US 2025/0311244 A1
(43) Pub. Date: Oct. 2, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventors: Hui Woo PARK, Gyeonggi-do (KR); Eun Seok CHOI, Gyeonggi-do (KR)

(21) Appl. No.: 18/776,260

(22) Filed: Jul. 18, 2024

(30) Foreign Application Priority Data
Mar. 26, 2024 (KR) 10-2024-0040987

(51) Int. Cl. H10B 80/00; H01L 23/00; H01L 25/00; H01L 25/065; H01L 25/18; H10B 41/27; H10B 43/27

(52) U.S. Cl. CPC H10B 80/00; H01L 24/08; H01L 24/80; H01L 25/0657; H01L 25/18; H01L 25/50; H10B 41/27; H10B 43/27; H01L 2224/08145; H01L 2224/80895; H01L 2224/80896; H01L 2924/1431; H01L 2924/14511

(57) ABSTRACT

A semiconductor device may include a first gate structure, a first source structure positioned over or on, e.g., as illustrated, on the first gate structure, first channel structures extending into the first source structure through the first gate structure, a second source structure positioned over or on, e.g., as illustrated, on the first source structure, a second gate structure positioned over or on, e.g., as illustrated, on the second source structure, second channel structures extending into the second source structure through the second gate structure, a bonding structure positioned between the first source structure and the second source structure, and a slit structure passing through the first gate structure, the first source structure, the bonding structure, the second source structure, and the second gate structure.

### CROSS-REFERENCE TO RELATED APPLICATION

This application claims priority under 35 U.S.C. § 119 to Korean Patent Application No. 10-2024-0040987 filed on Mar. 26, 2024, which is incorporated herein by reference in its entirety.

### BACKGROUND

### 1. Technical Field

Embodiments of the present disclosure relate generally to semiconductor devices, and more particularly, to a three-dimensional semiconductor device and a method of manufacturing the same.

### 2. Related Art

An integration degree of a semiconductor device, also known as integration density or component density, refers to how densely different components or functions are packed onto a single chip. That is, it measures how many transistors, resistors, capacitors, and other elements are integrated into an integrated circuit (IC). The integration degree is mainly determined by an area occupied by a unit memory cell, i.e., an electronic circuit that stores one bit of binary information. Recently, as improvements in the integration degree of a semiconductor device in which a memory cell is formed as a single layer on a substrate reach a limit, a three-dimensional (3-D) semiconductor device in which memory cells are stacked on a substrate has been proposed. In addition, various 3-D structures and manufacturing methods are being developed for improving the operational reliability and performance characteristics of 3-D semiconductor devices.

### SUMMARY

According to an embodiment of the present disclosure, a 3-D semiconductor device may include a first gate structure, a first source structure disposed over or on, e.g., as illustrated, on the first gate structure, first channel structures extending into the first source structure through the first gate structure, a second source structure disposed over or on, e.g., as illustrated, on the first source structure, a second gate structure disposed over or on, e.g., as illustrated, on the second source structure, second channel structures extending into the second source structure through the second gate structure, a bonding structure positioned between the first source structure and the second source structure, and a slit structure passing through the first gate structure, the first source structure, the bonding structure, the second source structure, and the second gate structure. For simplicity, a 3-D semiconductor device will be referred to simply as a semiconductor device.

According to an embodiment of the present disclosure, a method of manufacturing a semiconductor device may include forming a first cell wafer including a first stack including first material layers and second material layers alternately stacked, a first slit sacrificial layer extending through the first stack, and a first cell bonding pad positioned over or on, e.g., as illustrated, on the first stack, forming a second cell wafer including a second stack including third material layers and fourth material layers alternately stacked, a second slit sacrificial layer extending through the second stack, and a second cell bonding pad positioned over or on, e.g., as illustrated, on the second stack, bonding the first cell wafer and the second cell wafer so that the first cell bonding pad and the second cell bonding pad are connected, forming an opening by removing the second slit sacrificial layer, exposing the first slit sacrificial layer by expanding the opening, forming a slit by removing the first slit sacrificial layer, replacing the first material layers and the third material layers with fifth material layers through the slit, and forming a slit structure in the slit.

### BRIEF DESCRIPTION OF THE DRAWINGS

FIG. 1 is a simplified schematic diagram illustrating a semiconductor device according to an embodiment of the present disclosure.

FIGS. 2A to 2D are diagrams illustrating a semiconductor device according to an embodiment of the present disclosure.

FIGS. 3A to 3E are diagrams illustrating a method of manufacturing a semiconductor device according to an embodiment of the present disclosure.

FIGS. 4A to 10B are diagrams illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

According to the present technology, a semiconductor device having a stable structure and improved reliability may be provided.

Hereinafter, embodiments according to the technical spirit of the present disclosure are described with reference to the accompanying drawings.

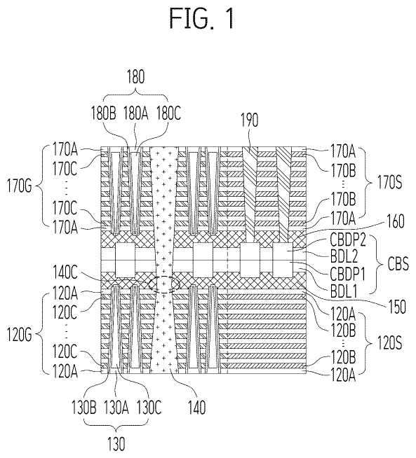

FIG. 1 is a simplified schematic diagram illustrating a semiconductor device according to an embodiment of the present disclosure.

Referring to FIG. 1, the semiconductor device may include a first stack 120S, a first gate structure 120G, a second stack 170S, a second gate structure 170G, first channel structures 130 spaced part from each other, second channel structures 180, a slit structure 140, a first source structure 150, a second source structure 160, a source plug 190, and a cell bonding structure CBS.

The first gate structure 120G may include first insulating layers 120A and first conductive layers 120C alternately stacked. The first stack 120S may be disposed at a level corresponding to the first gate structure 120G. The first stack 120S may include first insulating layers 120A and first sacrificial layers 120B alternately stacked. The first insulating layers 120A of the first gate structure 120G and the first insulating layers 120A of the first stack may be positioned at the same levels. That is, each of the insulating layers 120A may extend in both the first stack 120S and in the first gate structure 120G. The first conductive layers 120C of the first gate structure 120G and the first sacrificial layers 120B of the first stack 120S may be at same corresponding levels, i.e., each first conductive layer 120C may be at the same level with a corresponding first sacrificial layer 120B. The first insulating layers 120A may include an insulating material such as an oxide. The first sacrificial layers 120B may include a sacrificial material such as a nitride, and the first conductive layers 120C may include a conductive material such as tungsten, however, other metal materials may also be used.

The first source structure 150 may be positioned over or on, e.g., as illustrated, on the first gate structure 120G and on the first stack 120S. The first source structure 150 may be positioned over or on, e.g., as illustrated, on the top first insulating layer 120A of the first gate structure 120G and the first stack 120S. The first source structure 150 may also be formed over the tops of the first channel structures 130 which protrude through the top first insulating layer 120A. The second source structure 160 may be positioned on first source structure 150. The first and second source structures 150 and 160 may include a conductive material such as polysilicon.

The first channel structures 130 may extend into the first source structure 150 through the first gate structure 120G. Each of the first channel structures 130 may include a first channel layer 130A, a first memory layer 130B surrounding the first channel layer 130A, and a first insulating core 130C in the first channel layer 130A. For example, in the illustrated embodiment, the first channel layer 130A of the first channel structures 130 may be connected to the first source structure 150.

The second gate structure 170G may be positioned over or on, e.g., as illustrated, on the second source structure 160. The second gate structure 170G may include second insulating layers 170A and second conductive layers 170C alternately stacked. The second stack 170S may be disposed at a level corresponding to the second gate structure 170G. The second stack 170S may include second insulating layers 170A and second sacrificial layers 170B alternately stacked. The second insulating layers 170A of the second gate structure 170G and the second insulating layers 170A of the second stack 170S may be positioned at the same levels. That is, each of the second insulating layers 170A may extend in both the second stack 170S and in the second gate structure 170G. The second conductive layers 170C of the second gate structure 170G and the second sacrificial layers 170B of the second stack 170S may be at same corresponding levels, i.e., each second conductive layer 170C may be at the same level with a corresponding second sacrificial layer 170B. The second insulating layers 170A may include an insulating material such as an oxide, the second sacrificial layers 170B may include a sacrificial material such as a nitride, and the second conductive layers 170C may include a conductive material such as tungsten, however, other metal materials may also be used.

The second channel structures 180 are spaced apart from each other and extend in the stacking direction into the second source structure 160 through the second gate structure 170G. Each of the second channel structures 180 may include a second channel layer 180A, a second memory layer 180B surrounding the second channel layer 180A, and a second insulating core 180C in the second channel layer 180A. For example, in the illustrated embodiment, the second channel layer 180A of the second channel structures 180 may be connected to the second source structure 160.

The slit structure 140 may be disposed between the first channel structures 130 and between the second channel structures 180. The slit structure 140 may pass through the first gate structure 120G, the first source structure 150, the second source structure 160, and the second gate structure 170G. The slit structure 140 may have an inflection portion 140C at an upper surface of the first gate structure 120G. For example, the slit structure 140 may have the inflection portion 140C at the interface between the first gate structure 120G and the first source structure 150. An inclination of the side wall of the slit structure 140 may change or a step change may occur at the inflection portion 140C. For example, as shown in FIG. 1, the slit 140 may have a cross-section that is getting smaller from the bottom surface of the first gate structure 120G towards the top surface of the first gate structure 120G. From the inflection portion 140C towards the outermost surface (or top surface) of the second gate structure 170G the cross-section of the slit 140 may be getting larger. The slit structure 140 may have a constant or substantially constant size cross-section in its portion that passes through the first source structure 150. However, the slit structure 140 may vary in size in its portion that passes through the first source structure 150. For example, the slit structure 140 may have a cross-section that is getting larger from the inflection portion 140C toward the top surface of the first gate structure 120G. The slit structure 140 may include an insulating material such as an oxide.

The cell bonding structure CBS may be positioned between the first and second source structures 150 and 160. The cell bonding structure CBS may include a first bonding layer BDL1, a second bonding layer BDL2, a first cell bonding pad CBDP1, and a second cell bonding pad CBDP2. The first bonding layer BDL1 may be positioned over or on, e.g., as illustrated, on the first source structure 150. The second bonding layer BDL2 may be positioned between the first bonding layer BDL1 and the second source structure 160. The first bonding layer BDL1 and the second bonding layer BDL2 may be bonded. The first cell bonding pad CBDP1 may be disposed in the first source structure 150 and the first bonding layer BDL1. More specifically, as illustrated in FIG. 1, the first cell bonding pad CBDP1 may be passing through the first bonding layer BDL1 in the stacking direction and extend only partially inside the first source structure 150. The second cell bonding pad CBDP2 may be disposed in the second source structure 160 and the second bonding layer BDL2. More specifically, as illustrated in FIG. 1, the second cell bonding pad CBDP2 may be passing through the second bonding layer BDL2 in the stacking direction and extend only partially inside the second source structure 160. The first and second cell bonding pads CBDP1 and CBDP2 may be in direct contact. The first and second cell bonding pads CBDP1 and CBDP2 may be bonded.

The first and second bonding layers BDL1 and BDL2 may be made of an insulating material including, for example, an insulating material such as an oxide or nitride. Therefore, the first and second source structures 150 and 160 may be insulated by the first and second bonding layers BDL1 and BDL2. However, the first and second cell bonding pads CBDP1 and CBDP2 may be made of a conductive material including a conductive material such as copper. Therefore, according to an embodiment of the present disclosure, because the first and second cell bonding pads CBDP1 and CBDP2 are bonded, the first and second source structures 150 and 160 may be electrically connected through the first and second cell bonding pads CBDP1 and CBDP2.

The source plug 190 may pass through the second stack 170S and may extend only partially into the second source structure 160 to connect to the second cell bonding pad CBDP2. The semiconductor device may apply a bias to the second source structure 160 through the source plug 190. The source plug 190 may be electrically connected to the first source structure 150 through the second cell bonding pad CBDP2 and the first cell bonding pad CBDP1. Therefore, the semiconductor device may apply a bias to the second source structure 160 and the first source structure 150 through the source plug 190.

When only the second cell bonding pad CBDP2 and the first cell bonding pad CBDP1 are directly connected to the source plug 190, a source resistance may be large. According to an embodiment of the present disclosure, the first cell bonding pads CBDP1 and the second cell bonding pads CBDP2 that are not directly connected to the source plug 190 may be positioned between the first and second source structures 150 and 160 to thereby reduce the source resistance.

According to the structure described above, the semiconductor device may include the source plug 190 and a bias may be applied to the second source structure 160 and the first source structure 150 through the source plug 190. In addition, a resistance of the first and second source structures 150 and 160 may be reduced through the cell bonding structure CBS which are not directly connected to the source plugs 190.

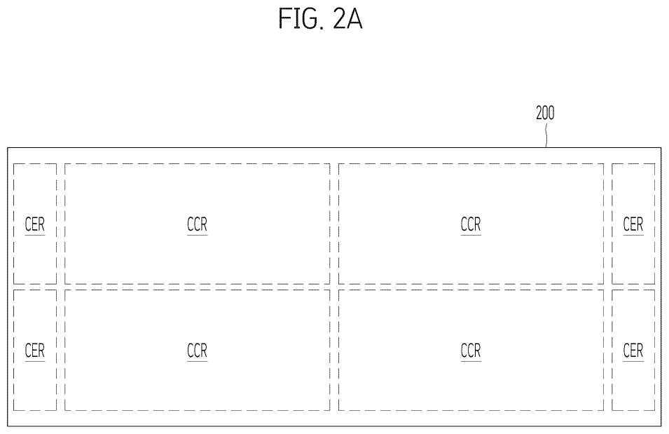

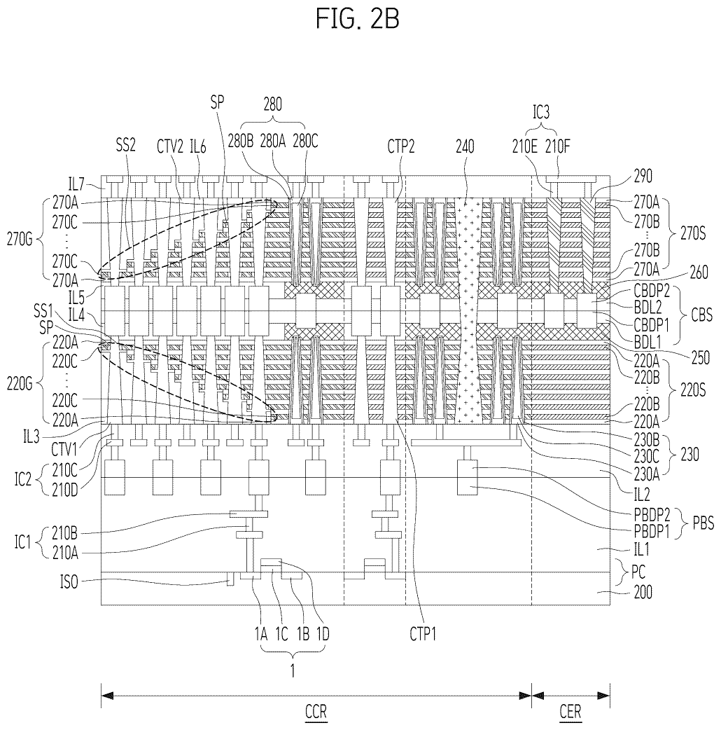

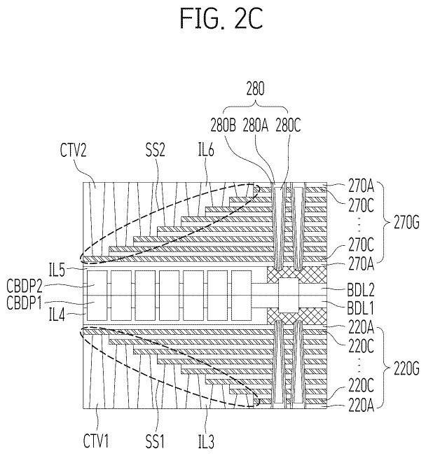

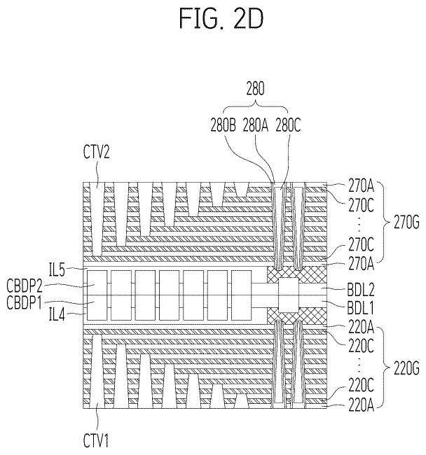

FIGS. 2A to 2D are diagrams illustrating a semiconductor device according to an embodiment of the present disclosure. FIG. 2A may be a plan view, FIG. 2B may be a cross-sectional view of FIG. 2A, and FIGS. 2C and 2D may be a portion of the cross-sectional view of FIG. 2A. Hereinafter, any content overlapping with the earlier description may be omitted.

Referring to the embodiment of FIGS. 2A and 2B, the semiconductor device may include a substrate 200, a first stack 220S, a first gate structure 220G, a second stack 270S, a second gate structure 270G, a plurality of first channel structures 230 spaced apart from each other, a plurality of second channel structures 280 spaced apart from each other, a slit structure 240, a first source structure 250, a second source structure 260, a source plug 290, a cell bonding structure CBS, and a peripheral circuit bonding structure PBS. The semiconductor device may further include at least one of a peripheral circuit PC, a first contact via CTV1, a second contact via CTV2, a first contact plug CTP1, a second contact plug CTP2, a first interconnection structure IC1, a second interconnection structure IC2, a third interconnection structure IC3, and first to seventh interlayer insulating layers IL1, IL2, IL3, IL4, IL5, IL6, and IL7. The first to seventh interlayer insulating layers IL1, IL2, IL3, IL4, IL5, IL6, and IL7 may be stacked over each other in the recited order, with the first interlayer insulating layer IL1 positioned over or on the substrate 200, or as illustrated in FIG. 2B on the substrate 200.

The substrate 200 may include a cell center region CCR and a cell end region CER. The cell end region CER may be positioned at one of both ends of the cell center region CCR. In the cell center region CCR, structures including the first source structure 250, the second source structure 260, the first channel structures 230, the second channel structures 280, the first contact via CTV1, the second contact via CTV2, the first contact plug CTP1, the second contact plug CTP2, and the like may be positioned, and in the cell end region CER, structures including the source plug 290 and the like may be positioned. As illustrated in the embodiment of FIG. 2B, the first source structure 250 and the second source structure 260 may extend from the cell center region CCR to the cell end region CER.

The peripheral circuit PC may be positioned over or on, e.g., as illustrated, on the substrate 200. For example, the peripheral circuit PC may be disposed in the cell center region CCR of the substrate 200. The peripheral circuit PC may include a transistor 1. The transistor 1 may be included in at least one of a page buffer and a row decoder. The transistor 1 may include junctions 1A and 1B, a gate electrode 1D, and a gate insulating layer 1C. For example, in the illustrated embodiment, the gate insulating layer 1C may be positioned between the gate electrode 1D and the substrate 200. An isolation layer ISO may be disposed in the substrate 200, and an active region of the transistor 1 may be defined by the isolation layer ISO.

The first interconnection structure IC1 may be positioned over or on, e.g., as illustrated, on the substrate 200. For example, the first interconnection structure IC1 may be disposed in the cell center region CCR. The first interconnection structure IC1 may be disposed in the first interlayer insulating layer IL1. For example, in the illustrated embodiment, the first interlayer insulating layer IL1 may be positioned on the substrate 200 and may cover the transistor 1 and the first interconnection structure IC1. The first interconnection structure IC1 may include first vias 210A extending in the stacking direction (e.g., the vertical direction) and first lines 210B extending in a direction parallel to the top surface of the substrate 200 (e.g., the horizontal direction). The first interconnection structure IC1 may be connected to the peripheral circuit PC. For example, at least one of the first vias 210A may be connected to the transistor 1. At least one of the first vias 210A may connect the first lines 210B to each other. The first lines 210B may connect the first vias 210A to each other. The first interconnection structure IC1 may include a conductive material such as tungsten, however, other metal materials may also be used. The first interlayer insulating layer IL1 may include an insulating material such as an oxide or nitride.

The peripheral circuit bonding structure PBS may be positioned over or on, e.g., as illustrated, on the first interconnection structure IC1. The peripheral circuit bonding structure PBS may include a first peripheral circuit bonding pad PBDP1 and a second peripheral circuit bonding pad PBDP2. The first peripheral circuit bonding pad PBDP1 may be disposed in the first interlayer insulating layer IL1. The second peripheral circuit bonding pad PBDP2 may be positioned over or on, e.g., as illustrated, on the first peripheral circuit bonding pad PBDP1. The second peripheral circuit bonding pad PBDP2 may be disposed in the second interlayer insulating layer IL2. For example, in the illustrated embodiment, the second interlayer insulating layer IL2 may be positioned over or on, e.g., as illustrated, on the first interlayer insulating layer IL1. The peripheral circuit bonding structure PBS may include a conductive material such as copper, and the second interlayer insulating layer IL2 may include an insulating material such as an oxide.

The second interconnection structure IC2 may be positioned over or on, e.g., as illustrated, on the peripheral circuit bonding structure PBS. The second interconnection structure IC2 may be disposed in the second interlayer insulating layer IL2. The second interconnection structure IC2 may include second vias 210C extending in the stacking direction and second lines 210D extending in a direction parallel to the top surface of the substrate 200. A portion of the second lines 210D may be used as a bit line. For example, among the second lines 210D, the second lines 210D connected to the first channel structures 230 may be used as the bit line. The second interconnection structure IC2 may be connected to the peripheral circuit bonding structure PBS. For example, at least one of the second vias 210C may be connected to the second peripheral circuit bonding pad PBDP2. The second interconnection structure IC2 may include a conductive material such as tungsten, however, other metal materials may also be used.

The first gate structure 220G may be disposed on a peripheral circuit bonding structure PBS. The first gate structure 220G may include first insulating layers 220A and first conductive layers 220C alternately stacked. For example, in the illustrated embodiment, the first conductive layers 220C may be gate lines. The gate lines may include at least one of a word line, a source select line, and a drain select line. The gate lines may be local lines connected to one or more global lines. The first stack 220S may be disposed at a level corresponding to the first gate structure 220G and may include first insulating layers 220A and first sacrificial layers 220B alternately stacked. The first stack 220S may be a remaining structure that is not replaced with the first gate structure 220G.

The first gate structure 220G may include a first step structure SS1. For example, the first gate structure 220G may include the first step structure SS1 in which an upper surface of at least one of the first conductive layers 220C is exposed. For example, in the illustrated embodiment, the first step structure SS1 may have an inverted shape. The third interlayer insulating layer IL3 may be positioned on the first step structure SS1.

The first contact vias CTV1 may extend through the first step structure SS1. For example, the first contact vias CTV1 may extend through the first step structure SS1 and may be electrically connected to the peripheral circuit PC. The first contact vias CTV1 may be positioned adjacent to the row decoder. The row decoder may activate the source select line, the word line, or the drain select line according to an address. In addition, the row decoder may transmit a voltage level of a global line to a local line. The first contact vias CTV1 may be connected to at least one of the first conductive layers 220C. For example, the first contact vias CTV1 may include a protrusion, and may be connected to the first conductive layer 220C, of which an upper surface is exposed through the first step structure SS1, through the protrusion of the first contact vias CTV1, respectively. An insulating spacer SP may be positioned between the first contact via CTV1 and the first conductive layers 220C. The insulating spacer SP may include an insulating material such as an oxide.

The first source structure 250 may extend from the cell center region CCR to the cell end region CER. The first source structure 250 may be positioned over or on, e.g., as illustrated, on the first gate structure 220G. The first source structure 250 may be positioned over or on, e.g., as illustrated, on the first stack 220S. The fourth interlayer insulating layer IL4 may be disposed at a level corresponding to the first source structure 250. The second source structure 260 may be positioned on first source structure 250. The second source structure 260 may extend from the cell center region CCR to the cell end region CER. The fifth interlayer insulating layer IL5 may be disposed at a level corresponding to the second source structure 260. The first and second source structures 150 and 160 may include a conductive material such as polysilicon.

The first channel structures 230 may extend into the first source structure 250 through the first gate structure 220G. Each of the first channel structures 230 may include a first channel layer 230A, a first memory layer 230B surrounding the first channel layer 230A, and a first insulating core 230C in the first channel layer 230A. For example, in the illustrated embodiment, the first channel layer 230A of the first channel structures 230 and the first source structure 250 may be connected.

The first contact plugs CTP1 may extend through the first stack 220S. For example, the first contact plugs CTP1 may extend through the first stack 220S and may be electrically connected to the peripheral circuit PC. The first contact plugs CTP1 may be connected to the first channel structures 230 through the second interconnection structure IC2. The first contact plugs CTP1 may be positioned adjacent to the page buffer. The page buffer may be connected to the bit line, a read operation or a program operation of a memory cell may be performed using the page buffer. For example, data sensed from a selected memory cell may be temporarily stored in a latch of the page buffer, or a voltage or a current of the bit line may be sensed during a read operation or a verify operation using the page buffer. According to an embodiment of the present disclosure, the first contact plugs CTP1 connected to the first channel structures 230 and the page buffer may be positioned adjacent to each other. Therefore, the page buffer may receive and sense the voltage or the current of the bit line at the shortest distance.

The cell bonding structure CBS may be positioned between the first source structure 250 and the second source structure 260. The cell bonding structure CBS may include a first bonding layer BDL1, a second bonding layer BDL2, a first cell bonding pad CBDP1, and a second cell bonding pad CBDP2. For example, in the illustrated embodiment, the first bonding layer BDL1 and the second bonding layer BDL2 may be bonded. The first and second cell bonding pads CBDP1 and CBDP2 may be bonded.

The second gate structure 270G may be positioned over or on, e.g., as illustrated, on the second source structure 260. The second gate structure 270G may include second insulating layers 270A and second conductive layers 270C alternately stacked. For example, in the illustrated embodiment, the second conductive layers 270C may be a gate line. The second stack 270S may be disposed at a level corresponding to the second gate structure 270G. The second stack 270S may include second insulating layers 270A and second sacrificial layers 270B alternately stacked.

The second gate structure 270G may include a second step structure SS2. For example, the second gate structure 270G may include the second step structure SS2 in which an upper surface of at least one of the second conductive layers 270C is exposed. For example, in the illustrated embodiment, the second step structure SS2 may be symmetrical to the first step structure SS1. The sixth interlayer insulating layer IL6 may be positioned over or on, e.g., as illustrated, on the first step structure SS1.

The second contact vias CTV2 may extend through the second step structure SS2 and may be electrically connected to the peripheral circuit PC. For example, the second contact vias CTV2 may extend through the second step structure SS2 and may be electrically connected to the peripheral circuit PC through the cell bonding structure CBS and the first contact vias CTV1. The second contact vias CTV2 may be electrically connected to the row decoder. The second contact vias CTV2 may be connected to at least one of the second conductive layers 270C. The insulating spacer SP may be positioned between the second contact via CTV2 and the second conductive layers 270C.

The second channel structures 280 may extend into the second source structure 260 through the second gate structure 270G. Each of the second channel structures 280 may include a second channel layer 280A, a second memory layer 280B surrounding the second channel layer 280A, and a second insulating core 280C in the second channel layer 280A. For example, in the illustrated embodiment, the second channel layer 280A of the second channel structures 280 and the second source structure 260 may be connected.

The second contact plugs CTP2 may extend through the second stack 270S and may be electrically connected to the peripheral circuit PC. For example, the second contact plugs CTP2 may extend through the second stack 270S and may electrically connect to the peripheral circuit PC through the cell bonding structure CBS and the first contact plugs CTP1. The second contact plugs CTP2 may be electrically connected to the page buffer.

The slit structure 240 may be positioned between the first channel structures 230 and between the second channel structures 280. The slit structure 240 may pass through the first gate structure 220G, the first source structure 250, the second source structure 260, and the second gate structure 270G. The slit structure 240 may have an inflection portion at an upper surface of the first gate structure 220G. The slit structure 140 may include an insulating material such as an oxide.

The source plug 290 may be disposed in the cell end region CER. The source plug 290 may extend into the second source structure 260 through the second stack 270S. The source plug 290 may be connected to the second cell bonding pad CBDP2. The semiconductor device may apply a bias to the second source structure 260 through the source plug 290. The source plug 290 may be electrically connected to the first source structure 250 through the second cell bonding pad CBDP2 and the first cell bonding pad CBDP1. Therefore, the semiconductor device may apply a bias to the second source structure 260 and the first source structure 250 through the source plug 290.

The third interconnection structure IC3 may be positioned over or on, e.g., as illustrated, on the second gate structure 270G or the second stack 270S. The third interconnection structure IC3 may be disposed in the seventh interlayer insulating layer IL7. For example, in the illustrated embodiment, the seventh interlayer insulating layer IL7 may be positioned over or on, e.g., as illustrated, on the second gate structure 270G or the second stack 270S. The third interconnection structure IC3 may include third vias 210E and third lines 210F. The third interconnection structure IC3 may include a conductive material such as tungsten, however, other metal materials may also be used. The first interlayer insulating layer IL1 may include an insulating material such as an oxide or nitride.

Referring to FIG. 2C, the first contact vias CTV1 may be connected to corresponding first conductive layers 220C of the first gate structure 220G. The second contact vias CTV2 may be connected to the second conductive layers 270C of the second gate structure 270G. Comparing to FIG. 2B, the first contact vias CTV1 may not extend through the first gate structure 220G, and the second contact vias CTV2 may not extend through the second gate structure 270G. In this case, the first contact vias CTV1 may be connected to an upper surface of the first conductive layers 220C exposed through the first step structure SS1 of the first gate structure 220G, and the second contact vias CTV2 may be connected to an upper surfaces of the exposed second conductive layers 270C through the second step structure SS2. For example, in the illustrated embodiment, the heights of the first contact vias CTV1 may be different from each other. Also, the heights of the second contact vias CTV2 may be different from each other.

Referring to FIG. 2D, the first gate structure 220G and the second gate structure 270G may not include a step structure. That is, the first gate structure 220G of FIGS. 2B and 2C may include the first step structure SS1, and the second gate structure 270G may include the second step structure SS2, however, the first gate structure 220G and the second gate structure 270G of FIG. 2D may not include a step structure. In the embodiment of FIG. 2D, the first contact vias CTV1 may extend through the first gate structure 220G and may be connected to the first conductive layers 220C, and the second contact vias CTV2 may extend through the second gate structure 270G and may be connected to the second conductive layers 270C. For example, in the illustrated embodiment, the heights of the first contact vias CTV1 may be different from each other, and, also, the heights of the second contact vias CTV2 may be different from each other.

For example, although omitted in FIG. 2D, a first insulating spacer may be positioned on a sidewall of the first contact via CTV1 for preventing the first conductive layers 220C other than the first conductive layer 220C connected to the first contact via CTV1 from being connected to the first contact via CTV1. Similarly, a second insulating spacer may be positioned on a sidewall of the second contact via CTV2. According to the structure described above, the peripheral circuit PC may include at least one of the page buffer and the row decoder. The page buffer may be positioned adjacent to the first contact plugs CTP1 connected to the bit line, and the row decoder may be positioned adjacent to the first contact vias CTV1. By positioning the page buffer and the bit line adjacent to each other, the program and read operations may be improved. Also, the row decoder and the first contact vias CTV1 may be disposed adjacent to each other, and, thus, the length of a bias transmission path is reduced.

The semiconductor device may include the source plug 290. The semiconductor device may apply a bias to the second source structure 260 and the first source structure 250 through the source plug 290. In addition, a resistance of the first source structure 250 and the second source structure 260 may be reduced because the cell bonding structure CBS is not directly connected to the source plugs 290.

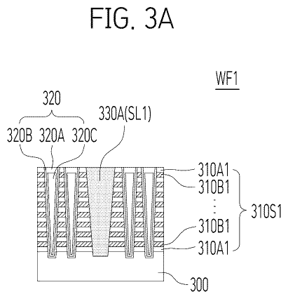

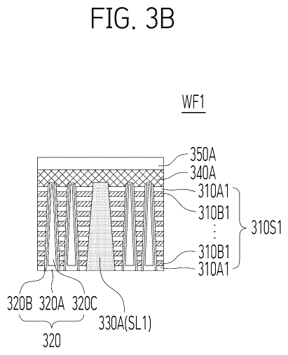

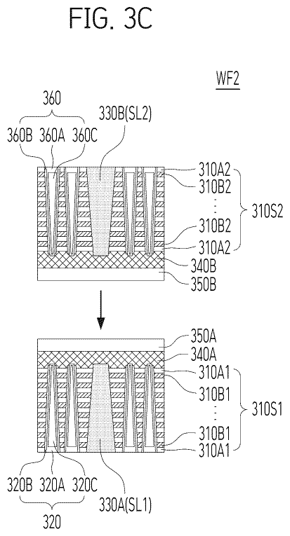

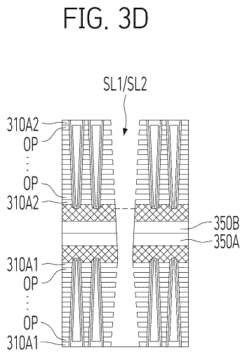

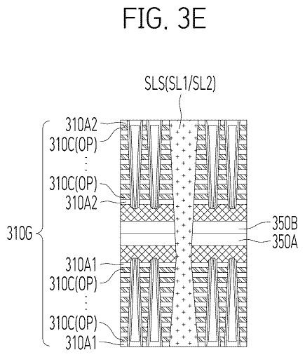

FIGS. 3A to 3E are diagrams illustrating a method of manufacturing a semiconductor device according to an embodiment of the present disclosure. Hereinafter, any content overlapping with content described earlier may be omitted.

Referring to FIG. 3A, a first wafer WF1 may be formed. A first stack 310S1 may be formed by alternately stacking first material layers 310A1 and second material layers 310B1. The first material layers 310A1 may include an insulating material such as an oxide, and the second material layers 310B1 may include a sacrificial material such as a nitride.

Subsequently, first channel structures 320 extending through the first stack 310S1 may be formed. For example, the first channel structures 320 extending into the substrate 300 through the first stack 310S1 may be formed. The first channel structures 320 may include a first channel layer 320A, a first memory layer 320B surrounding the first channel layer 320A, and a first insulating core 320C in the first channel layer 320A.

A first slit SL1 extending through the first stack 310S1 may be formed. For example, the first slit SL1 extending into the substrate 300 through the first stack 310S1 may be formed. The first slit SL1 may be formed between the first channel structures 320. Subsequently, a first slit sacrificial layer 330A may be formed in the first slit SL1. The first slit sacrificial layer 330A may include a sacrificial material such as tungsten or polysilicon.

Referring to FIG. 3B, the first wafer WF1 may be rotated. For example, the first wafer WF1 may be rotated by bonding the first wafer WF1 with a dummy substrate (not shown). Subsequently, the substrate 300 of the first wafer WF1 may be removed. Subsequently, a first source structure 340A connected to the first channel structures 320 may be formed. For example, in the illustrated embodiment, the first channel layer 320A of the first channel structures 320 may be connected to the first source structure 340A. Subsequently, a first bonding layer 350A may be formed on the first source structure 340A. For example, in the illustrated embodiment, the first bonding layer 350A may include an insulating material such as an oxide or nitride. For example, the first bonding layer 350A may include silicon carbon nitride (“Sic”).

Referring to FIG. 3C, a second wafer WF2 may be formed using an identical or similar method to the method of forming the first wafer WF1. For example, in the illustrated embodiment, the second wafer WF2 may include a second stack 310S2, a plurality of spaced apart second channel structures 360, a second slit sacrificial layer 330B, a second source structure 340B, and a second bonding layer 350B.

The second stack 310S2 may include third material layers 310A2 and fourth material layers 310B2 alternately stacked. Each of the second channel structures 360 may include a second channel layer 360A, a second memory layer 360B surrounding the second channel layer 360A, and a second insulating core 360C in the second channel layer 360A. The second source structure 340B may be connected to the second channel layer 360A of the second channel structures 360. The second bonding layer 350B may include, for example, SiCN.

Subsequently, the first wafer WF1 and the second wafer WF2 may be bonded. For example, the first bonding layer 350A and the second bonding layer 350B may be bonded. Because the first bonding layer 350A and the second bonding layer 350B may include SiCN, bonding strength may be improved at a bonding interface.

Referring to FIG. 3D, a second slit SL2 may be reopened by removing the second slit sacrificial layer 330B. Subsequently, the first slit sacrificial layer 330A may be exposed by expanding the second slit SL2. Subsequently, the first slit SL1 may be reopened by removing the first slit sacrificial layer 330A through the second slit SL2. Accordingly, the first slit SL1 and the second slit SL2 may be connected as one.

Subsequently, an opening OP may be formed by removing the second material layers 310B1 of the first stack 310S1 and the fourth material layers 310B2 of the second stack 310S2 through the first slit SL1 and the second slit SL2. That is, the second material layers 310B1 and the fourth material layers 310B2 of the first stack 310S1 and the second stack 310S2 may be removed simultaneously through the first slit SL1 and the second slit SL2. Therefore, a cost may be reduced by unifying a process compared to a case of removing each of the second material layers 310B1 and the fourth material layers 310B2.

Referring to FIG. 3E, fifth material layers 310C may be formed in the opening OP. For example, in the illustrated embodiment, the fifth material layers 310C may include a conductive material such as tungsten, however, other metal materials may also be used. Therefore, a gate structure 310G including the first material layers 310A1 and the fifth material layers 310C alternately stacked, and including the third material layers 310A2 and the fifth material layers 310C alternately stacked may be defined. For example, in the illustrated embodiment, the fifth material layers 310C of the gate structure 310G may be used as gate lines.

According to the manufacturing method described above, the second material layers 310B1 of the first stack 310S1 and the fourth material layers 310B2 of the second stack 310S2 may be removed simultaneously through the first slit SL1 and the second slit SL2 connected as one. Therefore, a cost may be reduced by unifying the process and reducing the process operations.

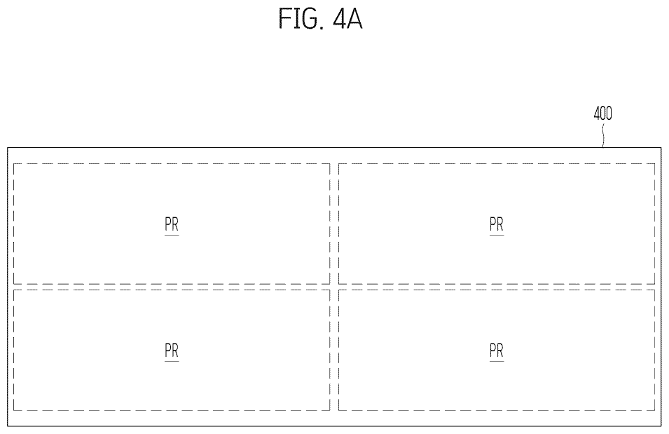

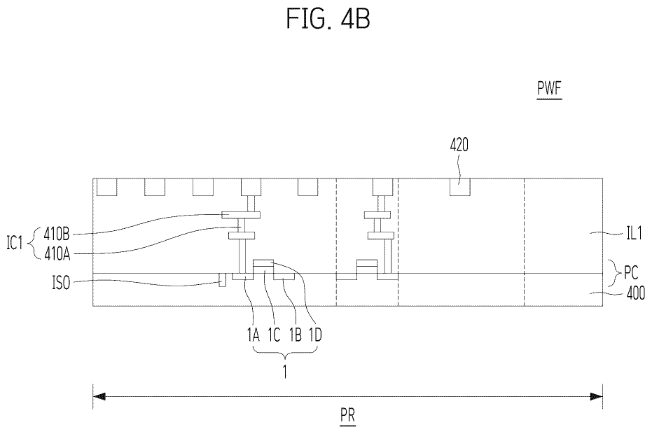

FIGS. 4A to 10B are diagrams illustrating a method of manufacturing a semiconductor device according to an embodiment of the present disclosure. Hereinafter, any content overlapping with the earlier description may be omitted.

Referring to FIGS. 4A and 4B, a peripheral circuit wafer PWF may be formed. First, a peripheral circuit PC may be formed over or on a first substrate 400. As illustrated in FIG. 4B, the peripheral circuit PC may be formed on the first substrate 400. The first substrate 400 may include a plurality of peripheral circuit regions PR. The peripheral circuit PC may be formed in the peripheral circuit regions PR. The peripheral circuit PC may include a transistor 1. The peripheral circuit PC may include at least one of a page buffer and a row decoder. The transistor 1 may be included in at least one of the page buffer and the row decoder. An isolation layer ISO may be formed in the first substrate 400 and may define an active region of the transistor 1.

A first interconnection structure IC1 may be formed on the first substrate 400. The first interconnection structure IC1 may be formed in the first interlayer insulating layer IL1. For example, in the illustrated embodiment, the first interlayer insulating layer IL1 may be formed on the first substrate 400. The first interconnection structure IC1 may include a first via 410A and a first line 410B. The first via 410A may be connected to the peripheral circuit PC. Alternatively, the first via 410A may connect the first lines 410B to each other. The first interconnection structure IC1 may include a conductive material such as tungsten, however, other metal materials may also be used. The first interlayer insulating layer IL1 may include an insulating material such as an oxide.

Subsequently, first peripheral circuit bonding pads 420 may be formed on the first interconnection structure IC1. For example, the first peripheral circuit bonding pad 420 may be formed on the peripheral circuit PC. The first peripheral circuit bonding pads 420 may be electrically connected to the peripheral circuit PC through the first interconnection structure IC1. The first peripheral circuit bonding pads 420 may include a conductive material such as copper.

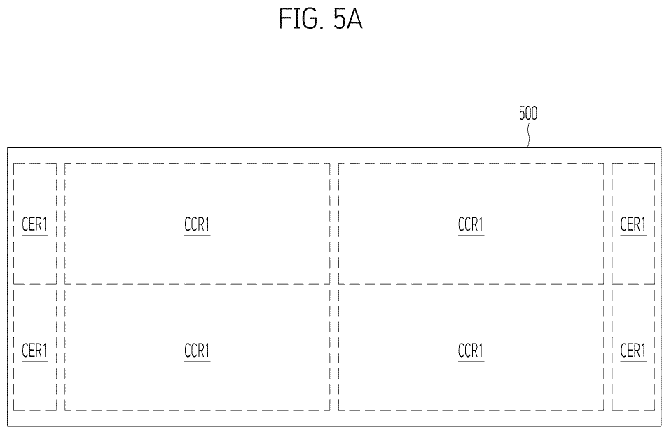

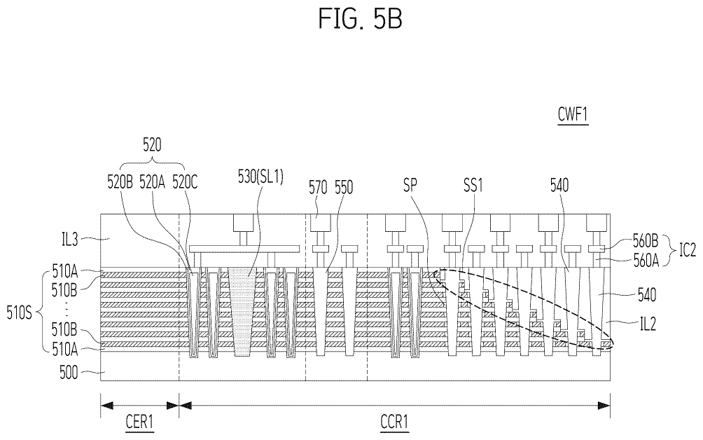

Referring to FIGS. 5A and 5B, a first cell wafer CWF1 may be formed. First, a first stack 510S may be formed on a second substrate 500. For example, in the illustrated embodiment, the second substrate 500 may include a first cell center region CCR1 and a first cell end region CER1. The first cell end region CER1 may be positioned at one of both ends of the first cell center region CCR1. The first stack 510S may extend from the first cell center region CCR1 to the first cell end region CER1. First material layers 510A may include an insulating material such as an oxide, and second material layers 510B may include a sacrificial material such as a nitride.

The first stack 510S may include the first material layers 510A and the second material layers 510B alternately stacked. The first stack 510S may include a first step structure SS1. For example, the first stack 510S may include the first step structure SS1 in which an upper surface of at least one of the second material layers 510B is exposed. The first step structure SS1 may be formed in the first cell center region CCR1. A second interlayer insulating layer IL2 may be formed on the first step structure SS1.

Subsequently, first channel structures 520 extending through the first stack 510S may be formed. The first channel structures 520 may be formed in the first cell center region CCR1. The first channel structures 520 may include a first channel layer 520A, a first memory layer 520B surrounding the first channel layer 520A, and a first insulating core 520C in the first channel layer 520A.

A first slit sacrificial layer 530 extending through the first stack 510S may be formed. First, a first slit SL1 extending through the first stack 510S may be formed. The first slit SL1 may be formed between the first channel structures 520. Subsequently, the first slit sacrificial layer 530 may be formed in the first slit SL1. For example, in the illustrated embodiment, the first slit sacrificial layer 530 may include a sacrificial material such as tungsten or polysilicon.

First contact vias 540 extending through the first stack 510S may be formed. For example, the first contact vias 540 may extend through the first step structure SS1. The first contact vias 540 may include protrusions and may be respectively connected to the second material layers 510B of which an upper surface is exposed through the protrusions. The first contact vias 540 may include a conductive material such as tungsten, however, other metal materials may also be used.

First contact plugs 550 extending through the first stack 510S may be formed. The first contact plugs 550 may be formed in the first cell center region CCR1. The first contact plugs 550 may be electrically connected to the first channel structures 520 through a second interconnection structure IC2. The first contact plugs 550 may include a conductive material such as tungsten, however, other metal materials may also be used.

Subsequently, the second interconnection structure IC2 may be formed on the first stack 510S. The second interconnection structure IC2 may be formed in a third interlayer insulating layer IL3. The third interlayer insulating layer IL3 may be formed on the first stack 510S. The second interconnection structure IC2 may include second vias 560A and second lines 560B. A portion of the second lines 560B may be used as a bit line. For example, among the second lines 560B, the second lines 560B connected to the first channel structures 520 may be used as the bit line.

Subsequently, second peripheral circuit bonding pads 570 may be formed on the second interconnection structure IC2. The second peripheral circuit bonding pads 570 may be formed in a third interlayer insulating layer IL3. The second peripheral circuit bonding pads 570 may include a conductive material such as copper.

For example, in the first cell end region CER1, other structures except for the first stack 510S may not be formed. However, the embodiments of the present disclosure are not limited thereto, and at least one of the first channel structures 520, the first contact plug 550, the second interconnection structure IC2, and the second peripheral circuit bonding pads 570 may be formed in the first cell end region CER1.

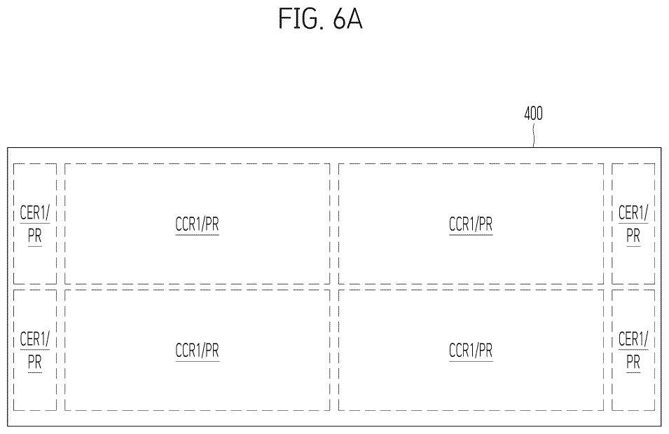

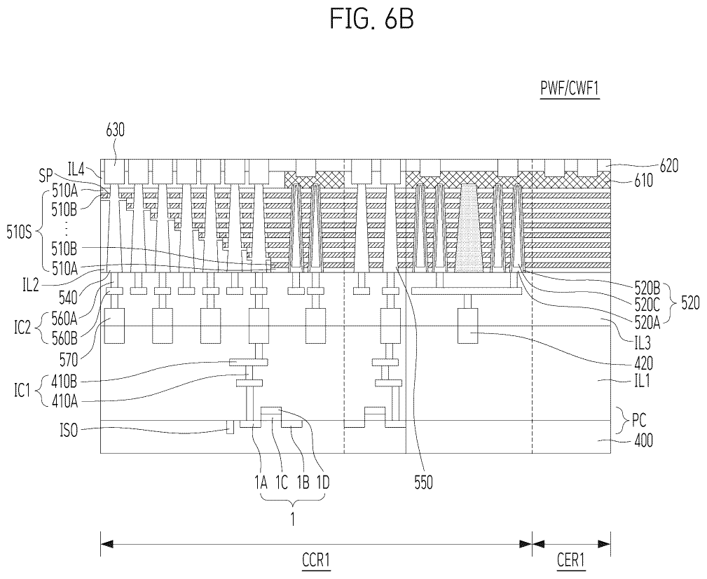

Referring to FIGS. 6A and 6B, the peripheral circuit wafer PWF and the first cell wafer CWF1 may be bonded. For example, the first peripheral circuit bonding pads 420 and the second peripheral circuit bonding pads 570 may be bonded. For example, in the illustrated embodiment, the first contact vias 540 and the first contact plugs 550 may be electrically connected to the peripheral circuit PC through the second peripheral circuit bonding pads 570 and the first peripheral circuit bonding pads 420. The first contact plugs 550 may be positioned adjacent to the page buffer, and the program operation and the read operation may be improved by disposing the page buffer and the bit line adjacent to each other. Because the first contact vias 540 may be positioned adjacent to the row decoder, a length of the bias transmission path may be reduced.

Subsequently, the second substrate 500 may be removed. Subsequently, the first source structure 610 may be formed on the first stack 510S. For example, the first source structure 610 may be formed to be connected with the first channel structures 520. For example, in the illustrated embodiment, the first channel layer 520A of the first channel structures 520 and the first source structure 610 may be connected. The first source structure 610 may extend from the first cell center region CCR1 to the first cell end region CER1. The fourth interlayer insulating layer IL4 may be formed in a region where the first source structure 610 is not formed.

Subsequently, a first bonding layer 620 may be formed on the first source structure 610. The first bonding layer 620 may include an insulating material such as an oxide or nitride. For example, the first bonding layer 620 may include SiCN.

Subsequently, the first cell bonding pads 630 may be formed in the first bonding layer 620. For example, the first cell bonding pads 630 may extend into the first source structure 610 through the first bonding layer 620. The first cell bonding pads 630 may extend through the first bonding layer 620 and may be connected to the first contact vias 540 and first contact plugs 550. The first cell bonding pads 630 may be formed in the first cell center region CCR1 and the first cell end region CER1. The first cell bonding pads 630 may include a conductive material such as copper.

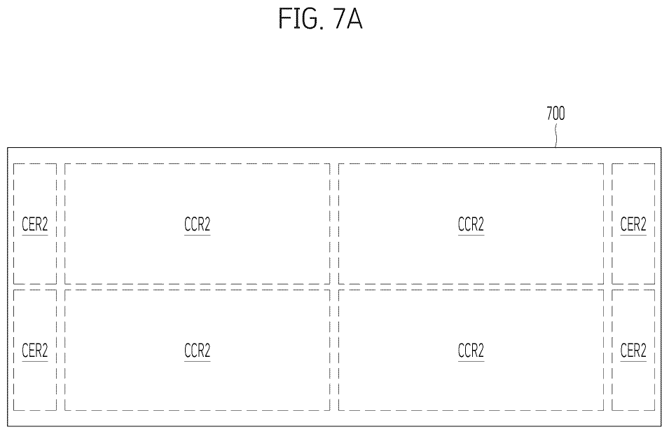

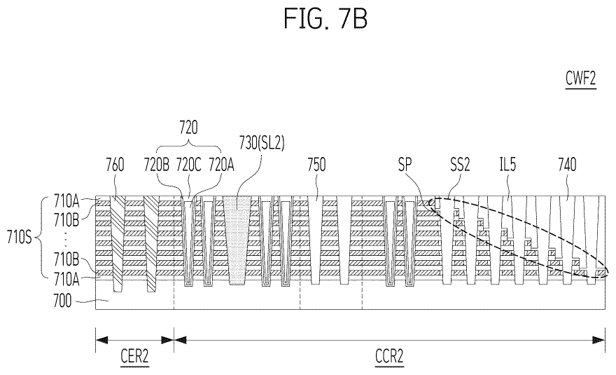

Referring to FIGS. 7A and 7B, a second cell wafer CWF2 may be formed. For example, the second cell wafer CWF may be formed in a method equal or similar to that of the first cell wafer CWF1 of FIG. 5B. The second cell wafer CWF2 may include a second stack 710S including third material layers 710A and fourth material layers 710B alternately stacked, and a second slit sacrificial layer 730 extending through the second stack 710S. The second cell wafer CWF2 may include channel structures 720 extending through the second stack 710S, second contact vias 740 extending through the second stack 710S, and second contact plugs 750 extending through the second stack 710S. In addition, the second cell wafer CWF2 may form a source plug 760 extending through the second stack 710S. For example, in the illustrated embodiment, when forming the second contact vias 740 and the second contact plug 750, the source plug 760 may be formed. For example, in the illustrated embodiment, the source plug 760 may include a conductive material such as tungsten, however, other metal materials may also be used.

The second stack 710S may be formed on a third substrate 700. The third substrate 700 may include a second cell center region CCR2 and a second cell end region CER2. The second stack 710S may include a second step structure SS2. For example, the second stack 710S may include the second step structure SS2 in which an upper surface of at least one of the fourth material layers 710B is exposed. The second step structure SS2 may be symmetrical to the first step structure SS1. A fifth interlayer insulating layer IL5 may be formed on the second step structure SS2. The second channel structures 720 may include a second channel layer 720A, a second memory layer 720B surrounding the second channel layer 720A, and a second insulating core 720C in the second channel layer 720A. The second slit sacrificial layer 730 may be formed in a second slit SL2. The second slit sacrificial layer 730 may include a sacrificial material such as tungsten or polysilicon. The second contact vias 740 may extend through the second step structure SS2. The second contact vias 740 may include protrusions and may be respectively connected to the fourth material layers 710B of which an upper surface is exposed through the protrusions. The second contact vias 740 may include a conductive material such as tungsten, however, other metal materials may also be used. The second contact plugs 750 may be formed in the first cell center region CCR1. The second contact plugs 750 may include a conductive material such as tungsten, however, other metal materials may also be used.

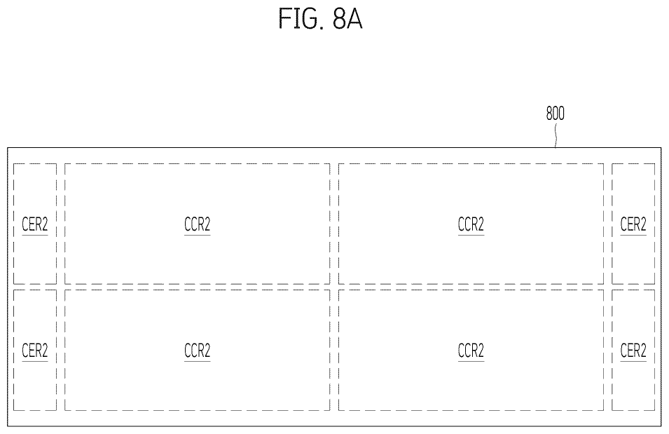

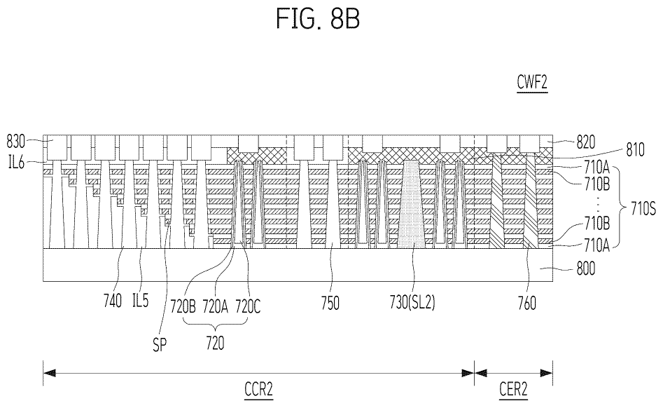

Referring to FIGS. 8A and 8B, the second cell wafer CWF2 may be rotated. For example, the second cell wafer CWF2 may be bonded on a carrier substrate 800. Subsequently, the second channel structures 720 may be exposed by removing the third substrate 700. Subsequently, a second source structure 810 connected to the second channel structures 720 may be formed. For example, in the illustrated embodiment, the second channel layer 720A of the second channel structures 720 and the second source structure 810 may be connected, and the source plug 760 and the second source structure 810 may be connected. That is, the second source structure 810 may extend from the second cell center region CCR2 to the second cell end region CER2. A sixth interlayer insulating layer IL6 may be formed in a region where the second source structure 810 is not formed.

Subsequently, a second bonding layer 820 may be formed on the second source structure 810. The second bonding layer 820 may include an insulating material such as an oxide or nitride. For example, the second bonding layer 820 may include SiCN.

Subsequently, second cell bonding pads 830 may be formed in the second bonding layer 820. For example, the second cell bonding pads 830 may extend into the second source structure 810 through the second bonding layer 820. The second cell bonding pads 830 may extend through the second bonding layer 820 and may be connected to the second contact vias 740 and the second contact plugs 750. In addition, the second cell bonding pads 830 may extend through the second bonding layer 820 and may be connected to the source plugs 760. The second cell bonding pads 830 may be formed in the second cell center region CCR2 and the second cell end region CER2. The second cell bonding pads 830 may include a conductive material such as copper.

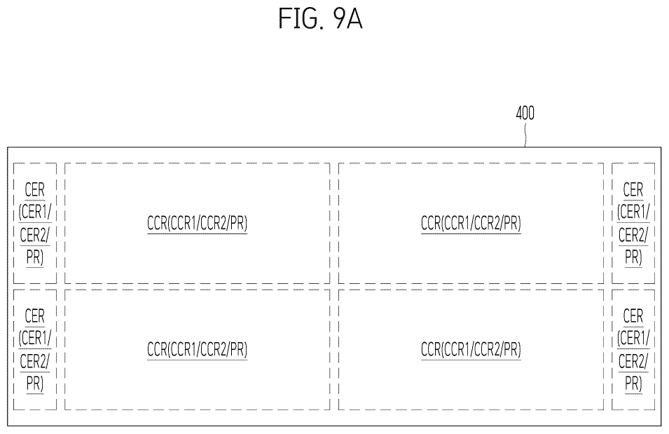

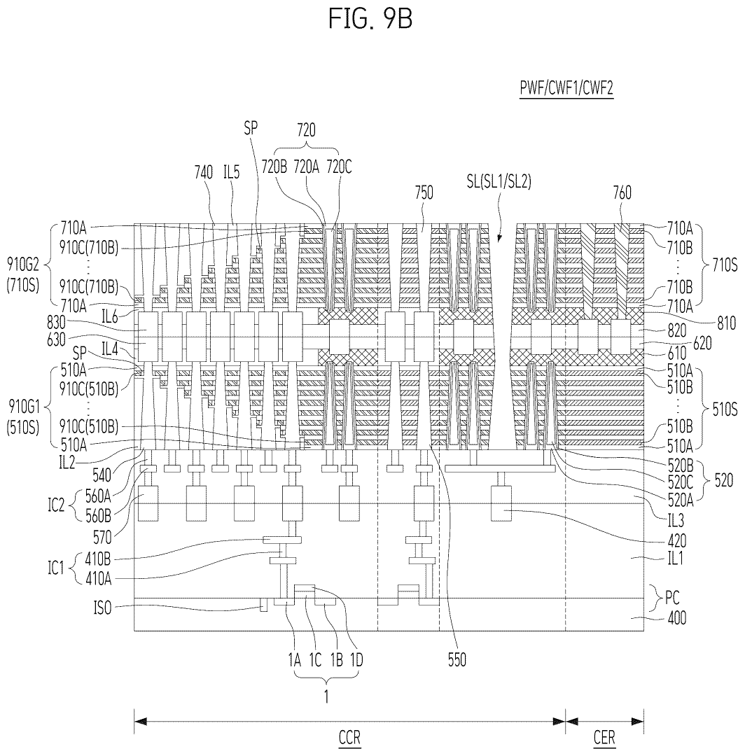

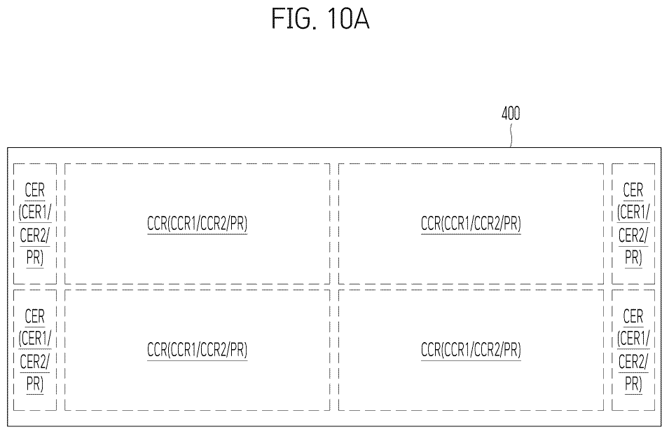

Referring to FIGS. 9A and 9B, the first cell wafer CWF1 and the second cell wafer CWF2 may be bonded. For example, the first cell wafer CWF1 and the second cell wafer CWF2 may be bonded so that the first cell center region CCR1 and the second cell center region CCR2 face each other and the first cell end region CER1 and the second cell end region CER2 face each other. For example, in the illustrated embodiment, a region where the first cell center region CCR1, the second cell center region CCR2, and the peripheral circuit region PR overlap with each other may be defined as a cell center region CCR, and a region where the first cell end region CER1, the second cell end region CER2, and the peripheral circuit region PR overlap with each other may be defined as a cell end region CER.

The first cell bonding pads 630 and the second cell bonding pads 830 may be bonded. For example, the first cell bonding pads 630 and the second cell bonding pads 830 of the cell center region CCR may be bonded, and the first cell bonding pads 630 and the second cell bonding pads 830 of the cell end region CER 630 may be bonded. In addition, the first bonding layer 620 and the second bonding layer 820 may be bonded. Because the first bonding layer 620 and the second bonding layer 820 may include SiCN, bonding strength may be improved at a bonding interface.

The source plug 760 may be connected to the second cell bonding pad 830. Therefore, the source plug 760 may be electrically connected to the first source structure 610 through the second cell bonding pad 830 and the first cell bonding pad 630. The semiconductor device may apply a bias to the second source structure 810 and the first source structure 610 through the source plug 760.

When only the second cell bonding pad 830 and the first cell bonding pad 630 directly connected to the source plug 760 exist, a source resistance may be large. According to an embodiment of the present disclosure, the first cell bonding pads 630 and the second cell bonding pads 830 that are not directly connected to the source plug 760 may be formed between the first source structure 610 and the second source structure 810. Therefore, the source resistance may be reduced.

Subsequently, the second slit SL2 may be reopened by removing the second slit sacrificial layer 730. For example, in the illustrated embodiment, the second slit SL2 refers to an opening. Subsequently, the first slit sacrificial layer 530 may be exposed by expanding the second slit SL2. For example, the first slit sacrificed layer 530 may be exposed by etching the second source structure 810, the second bonding layer 820, the first bonding layer 620, and the first source structure 610 through the second slit SL2. Subsequently, a slit SL may be formed by removing the first slit sacrificial layer 530. For example, in the illustrated embodiment, the slit SL refers to the first slit SL1 and the expanded second slit SL2 connected to the first slit SL1.

Subsequently, the second material layers 510B of the first stack 510S and the fourth material layers 710B of the second stack 710S may be replaced with fifth material layers 910C through the slit SL. For example, the second material layers 510B and the fourth material layers 710B may be removed through the slit SL. Subsequently, the fifth material layers 910C may be formed in a region formed by removing the second material layers 510B and the fourth material layers 710B. Therefore, a gate structure 910G including the first material layers 510A and the fifth material layers 910C alternately stacked and including the third material layers 710A and the fifth material layers 910C alternately stacked may be defined. For example, in the illustrated embodiment, the fifth material layers 910C of the gate structure 910G may be used as a gate line. The fifth material layers 810C may include a conductive material such as tungsten, however, other metal materials may also be used.

According to an embodiment of the present disclosure, the second material layers 510B and the fourth material layers 710B of the first stack 510S and the second stack 710S may be removed simultaneously through the slit SL. Therefore, a cost may be reduced by unifying a process compared to a case of removing the second material layers 510B and the fourth material layers 710B separately.

For example, a process of replacing the second material layers 510B of the first stack 510S and the fourth material layers 710B of the second stack 710S with the fifth material layers 910C may be omitted in a partial region. For example, the process of replacing the cell end region CER with fifth material layers 910C may be omitted. In addition, a process of replacing a region where the first contact plugs 550 and the second contact plugs 750 are formed with the fifth material layers 910C may be omitted in the cell center region CCR.

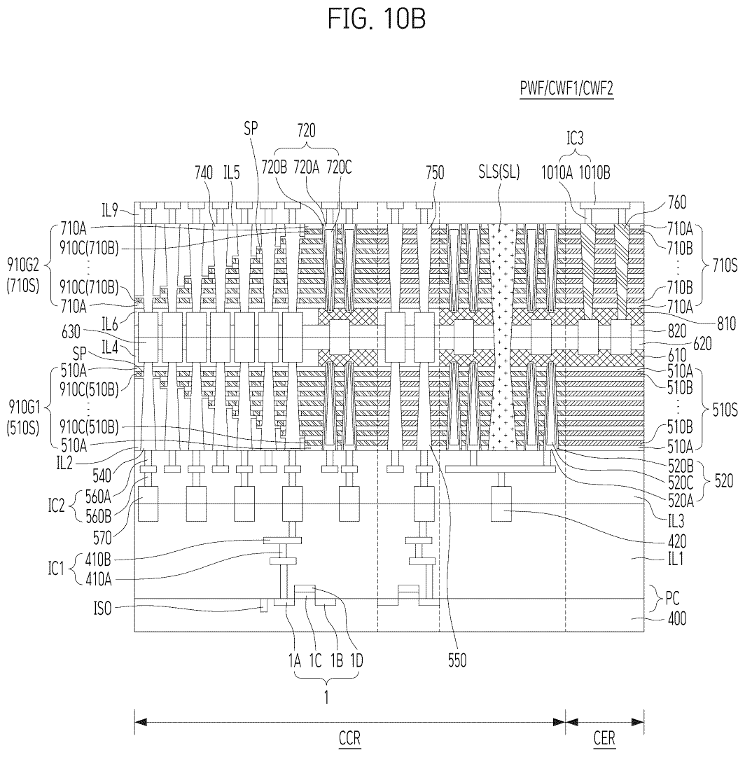

Referring to FIGS. 10A and 10B, a slit structure SLS may be formed in the slit SL. The slit structure SLS may include an insulating material such as an oxide.

Subsequently, a ninth interlayer insulating layer IL9 may be formed on the second stack 710S and the second gate structure 910G. Subsequently, a third interconnection structure IC3 may be formed in the ninth interlayer insulating layer IL9. The third interconnection structure IC3 may include a third via 1010A and a third line 1010B. At least one of the third vias 1010A may be connected to the source plug 760. At least one of the third vias 1010A may be connected to at least one of the second channel structures 720, the second contact vias 740, and the second contact plugs 750.

According to the manufacturing method described above, the second material layers 510B of the first stack 510S and the fourth material layers 710B of the second stack 710S may be removed simultaneously through the slit SL. Therefore, a cost may be reduced by unifying a process.

In addition, the source plug 760 may be formed. The semiconductor device may apply a bias to the second source structure 810 and the first source structure 610 through the source plug 760. In addition, a resistance of the first source structure 610 and the second source structure 810 may be reduced through the first cell bonding pads 630 and the second cell bonding pads 830 that are not directly connected to the source plugs 760.

Although embodiments according to the technical spirit of the present disclosure have been described with reference to the accompanying drawings, this is only for describing an embodiment according to the concept of the present disclosure, and the present disclosure is not limited to the above-described embodiments. Within the scope of the technical spirit of the present disclosure described in the claims, various forms of substitution, modification, and change of the embodiments will be possible by those skilled in the art to which the present disclosure belongs, and these also belong to the scope of the present disclosure.

What is claimed is:

1. A semiconductor device comprising:
a first gate structure;
a first source structure disposed over the first gate structure;
first channel structures extending into the first source structure through the first gate structure;
a second source structure disposed over the first source structure;
a second gate structure disposed over the second source structure;
second channel structures extending into the second source structure through the second gate structure;
a bonding structure disposed between the first source structure and the second source structure; and
a slit structure passing through the first gate structure, the first source structure, the bonding structure, the second source structure, and the second gate structure.

2. The semiconductor device of claim 1, wherein the bonding structure comprises:
a first bonding layer disposed on the first source structure;
a second bonding layer disposed between the first bonding layer and the second source structure;
a first cell bonding pad disposed in the first source structure and the first bonding layer; and
a second cell bonding pad disposed in the second source structure and the second bonding layer and bonded to the first cell bonding pad.

3. The semiconductor device of claim 2, further comprising:
a first stack disposed at a level corresponding to the first gate structure;
a second stack disposed at a level corresponding to the second gate structure; and
a source plug extending into the second source structure through the second stack.

4. The semiconductor device of claim 3, wherein the source plug is connected to the second cell bonding pad, and wherein a bias is applied to the first source structure and the second source structure through the source plug.

5. The semiconductor device of claim 4, wherein the source plug is electrically connected to the first source structure through the second cell bonding pad and the first cell bonding pad.

6. The semiconductor device of claim 1, wherein the slit structure includes a curved portion on an upper surface of the first gate structure.

7. The semiconductor device of claim 1, wherein the first gate structure includes a first step structure, and the second gate structure includes a second step structure symmetrical to the first step structure.

8. The semiconductor device of claim 1, further comprising:
a peripheral circuit positioned under the first gate structure;
a first stack disposed at a level corresponding to the first gate structure;
a first contact plug extending through the first stack and electrically connected to the peripheral circuit;
a second stack disposed at a level corresponding to the second gate structure; and
a second contact plug extending through the second stack and connected to the first peripheral circuit plug through the bonding structure.

9. The semiconductor device of claim 8, wherein the first gate structure includes a first step structure, and the second gate structure includes a second step structure symmetrical to the first step structure.

10. The semiconductor device of claim 9, further comprising:
a first contact via extending through the first step structure and electrically connected to the peripheral circuit; and
a second contact via extending through the second step structure and connected to the first contact via through the bonding structure.

11. The semiconductor device of claim 10, wherein the peripheral circuit includes at least one of a page buffer and a row decoder.

12. The semiconductor device of claim 11, wherein the page buffer is positioned adjacent to the first contact plug, and the row decoder is positioned adjacent to the first contact via.

13. A method of manufacturing a semiconductor device, the method comprising:
forming a first cell wafer including a first stack including first material layers and second material layers alternately stacked, a first slit sacrificial layer extending through the first stack, and a first cell bonding pad positioned over the first stack;
forming a second cell wafer including a second stack including third material layers and fourth material layers alternately stacked, a second slit sacrificial layer extending through the second stack, and a second cell bonding pad positioned over the second stack;
bonding the first cell wafer and the second cell wafer so that the first cell bonding pad and the second cell bonding pad are connected;
forming an opening by removing the second slit sacrificial layer;
exposing the first slit sacrificial layer by expanding the opening;
forming a slit by removing the first slit sacrificial layer;
replacing the first material layers and the third material layers with fifth material layers through the slit; and
forming a slit structure in the slit.

14. The method of claim 13, wherein forming the first cell wafer comprises:
forming a first source structure on the first stack;
forming a first bonding layer on the first source structure; and
forming the first cell bonding pad in the first bonding layer.

15. The method of claim 14, wherein forming the second cell wafer comprises:
forming a second source structure on the second stack;
forming a second bonding layer on the second source structure; and
forming the second cell bonding pad in the second bonding layer.

16. The method of claim 15, further comprising:
forming a source plug connected to the second source structure through the second stack.

17. The method of claim 16, wherein the source plug is electrically connected to the first source structure through the second cell bonding pad and the first cell bonding pad.

18. The method of claim 13, further comprising:
forming a peripheral circuit wafer including a peripheral circuit and a first peripheral circuit bonding pad positioned over the peripheral circuit.

19. The method of claim 18, wherein forming the first cell wafer comprises forming a second peripheral circuit bonding pad on the first stack.

20. The method of claim 19, further comprising:
bonding the peripheral circuit wafer and the first cell wafer so that the first peripheral circuit bonding pad and the second peripheral circuit bonding pad are connected.

21. The method of claim 20, wherein forming the first cell wafer comprises forming the first cell bonding pad on the first stack, after bonding the peripheral circuit wafer and the first cell wafer.

22. The method of claim 18, wherein the first cell wafer further includes a first contact plug extending through the first stack and connected to the peripheral circuit, and
the second cell wafer further includes a second contact plug extending through the second stack and connected to the first contact plug.

23. The method of claim 22, wherein the first contact plug and the second contact plug are connected through the first cell bonding pad and the second cell bonding pad.

24. The method of claim 18, wherein the first stack includes a first step structure,
the second stack includes a second step structure symmetrical to the first step structure,
the first cell wafer further includes a first contact via extending through the first step structure and connected to the peripheral circuit, and
the second cell wafer further includes a second contact via extending through the second step structure and connected to the first contact via.

25. The method of claim 24, wherein the first contact via and the second contact via are connected through the first cell bonding pad and the second cell bonding pad.

26. The method of claim 18, wherein the peripheral circuit includes at least one of a page buffer and a row decoder.
